(19) United States
(12) Patent Application Publication
(10) Pub. No.: US 2026/0255692 A1
(43) Pub. Date: Aug. 27, 2026

(54) POWER-GENERATION MODULE, METHOD FOR MANUFACTURING POWER-GENERATION MODULE, AND COATING DEVICE

(71) Applicant: Panasonic Intellectual Property Management Co., Ltd., Osaka (JP)

(72) Inventors: Naoki TAMBO, Kyoto (JP); Teruaki YAMAMOTO, Osaka (JP); Hiroko IKESHIMA, Osaka (JP); Daiji KANEMATSU, Osaka (JP); Toru NAKAMURA, Osaka (JP); Taisuke MATSUI, Osaka (JP)

(73) Assignee: Panasonic Intellectual Property Management Co., Ltd., Osaka (JP)

(21) Appl. No.: 19/651,655

(22) Filed: Apr. 18, 2026

Related U.S. Application Data
(63) Continuation of application No. PCT/JP2024/039747, filed on Nov. 8, 2024.

(30) Foreign Application Priority Data
Nov. 10, 2023 (JP) 2023-192550

(51) Int. Cl. H10F 19/80; B05C 5/02

(52) U.S. Cl. CPC H10F 19/80; B05C 5/027

(57) ABSTRACT

A method for manufacturing a power-generation module having a photovoltaic cell and a sealing member arranged between a first substrate and a second substrate comprises, around a photovoltaic cell, applying a material for a first sealing member and applying a material for a second sealing member to the outside of the first sealing member.

### CROSS REFERENCE TO RELATED APPLICATION

This application claims benefit of priority to International Patent Application No. PCT/JP 2024/039747 filed Nov. 8, 2024, the entire contents of which are incorporated herein by reference.

### BACKGROUND

### Technical Field

The present disclosure relates to a power-generation module used for photovoltaic power generation such as building integrated photovoltaics (BIPV), a method for manufacturing the power-generation module, and an coating device.

### Background Art

Conventionally, a power generation module of this type is known, for example, from WO2021/251048. The power-generation module described in WO2021/251048 includes a first substrate and a second substrate disposed facing each other in the thickness direction, and a solar cell and a sealing layer disposed between the first substrate and the second substrate.

The power-generation module of WO2021/251048 still has room for improvement in terms of sealability.

### SUMMARY

Therefore, an object of the present disclosure is to solve the above problem and to provide a power-generation module that can improve sealability, a method for manufacturing the power-generation module, and an coating device.

A manufacturing method of a power-generation module according to the present disclosure is a method for manufacturing a power-generation module in which a photovoltaic cell and a sealing member are arranged between a first substrate and a second substrate, the method comprising: applying, around the photovoltaic cell, a material for a first sealing member and a material for a second sealing member disposed outside the first sealing member.

An coating device according to the present disclosure comprises: a first dispensing port for dispensing a material for a first sealing member and a second dispensing port for dispensing a material for a second sealing member disposed outside the first sealing member, the first and second dispensing ports configured so that the materials for the first sealing member and the second sealing member are applied around a photovoltaic cell disposed between a first substrate and a second substrate of a power-generation module.

An coating device according to the present disclosure comprises: a first dispensing port for dispensing a material for a first sealing member to an Nth dispensing port for dispensing a material for an Nth sealing member (N≥2), the first to Nth dispensing ports configured so that the materials for the first sealing member to the Nth sealing member (N≥2) are applied in order from the inside out around a photovoltaic cell between a first substrate and a second substrate of a power-generation module.

A power-generation module according to the present disclosure comprises: a first substrate and a second substrate arranged spaced apart from each other in a thickness direction; a photovoltaic cell disposed between the first substrate and the second substrate; and a sealing member disposed around the photovoltaic cell, wherein the sealing member includes an internal sealing member and an external sealing member disposed outside the internal sealing member, wherein the internal sealing member and the external sealing member are made of different types of materials, and wherein when viewed from the thickness direction, the external sealing member is disposed in a plurality of layers.

According to the present disclosure, sealability can be improved.

### BRIEF DESCRIPTION OF DRAWINGS

FIG. 1 is a longitudinal cross-sectional view (cross-sectional view taken along line II-II in FIG. 2) of a power-generation module according to a first embodiment;

FIG. 2 is a transverse cross-sectional view (cross-sectional view taken along line II in FIG. 1) of the power-generation module according to the first embodiment;

FIG. 3 is a flowchart showing the flow of a manufacturing method of the power-generation module shown in FIGS. 1 and 2;

FIG. 4A is a longitudinal cross-sectional view for explaining the manufacturing method of the power-generation module according to the flowchart of FIG. 3;

FIG. 4B is a longitudinal cross-sectional view for explaining the manufacturing method of the power-generation module according to the flowchart of FIG. 3;

FIG. 4C is a longitudinal cross-sectional view for explaining the manufacturing method of the power-generation module according to the flowchart of FIG. 3;

FIG. 4D is a longitudinal cross-sectional view for explaining the manufacturing method of the power-generation module according to the flowchart of FIG. 3;

FIG. 4E is a longitudinal cross-sectional view illustrating the manufacturing method of the power-generation module according to the flowchart of FIG. 3;

FIG. 4F is a longitudinal cross-sectional view for explaining the manufacturing method of the power-generation module according to the flowchart of FIG. 3;

FIG. 4G is a longitudinal sectional view for explaining the manufacturing method of the power-generation module according to the flowchart of FIG. 3;

FIG. 5 is a plan view of an coating device (for an internal sealing member) according to the first embodiment;

FIG. 6 is a plan view of the coating device (for an external sealing member) according to the first embodiment;

FIG. 7 is a flowchart showing the flow of an application process (S4) of the internal sealing member according to the first embodiment;

FIG. 8A is a transverse cross-sectional view for explaining the application process according to the flowchart of FIG. 7;

FIG. 8B is a transverse cross-sectional view for explaining the application process according to the flowchart of FIG. 7;

FIG. 9 is a flowchart showing the flow of an application process (S5) of the external sealing member according to the first embodiment;

FIG. 10A is a transverse cross-sectional view for explaining the application process according to the flowchart of FIG. 9;

FIG. 10B is a transverse cross-sectional view for explaining the application process according to the flowchart of FIG. 9;

FIG. 10C is a transverse cross-sectional view for explaining the application process according to the flowchart of FIG. 9;

FIG. 10D is a transverse cross-sectional view for explaining the application process according to the flowchart of FIG. 9;

FIG. 10E is a transverse cross-sectional view for explaining the application process according to the flowchart of FIG. 9;

FIG. 10F is a transverse cross-sectional view for explaining the application process according to the flowchart of FIG. 9;

FIG. 10G is a transverse cross-sectional view for explaining the application process according to the flowchart of FIG. 9;

FIG. 10H is a transverse cross-sectional view for explaining the application process according to the flowchart of FIG. 9;

FIG. 10I is a transverse cross-sectional view for explaining the application process according to the flowchart of FIG. 9;

FIG. 10J is a transverse cross-sectional view for explaining the application process according to the flowchart of FIG. 9;

FIG. 11 is a plan view of an coating device according to a variant of the first embodiment;

FIG. 12 is a plan view of an coating device according to another variant of the first embodiment;

FIG. 13 is a transverse cross-sectional view of a power-generation module according to a second embodiment; and

FIG. 14 is a plan view of an coating device (for an external sealing member) according to the second embodiment.

### DETAILED DESCRIPTION

### Embodiments

Hereinafter, embodiments of the present disclosure will be described with reference to the drawings. In the following description, terms indicating specific directions or positions (e.g., terms including “up,” “down,” “right,” and “left”) will be used as necessary. However, the use of these terms is intended to facilitate understanding of the present disclosure with reference to the drawings, and the meanings of these terms do not limit the technical scope of the present disclosure or the manner of use of the power-generation module according to the present disclosure. Also, the following description is merely exemplary in nature and is not intended to limit the present disclosure, its applications, or its uses. Furthermore, the drawings are schematic, and the proportions of the dimensions do not necessarily correspond to the actual ones.

### First Embodiment

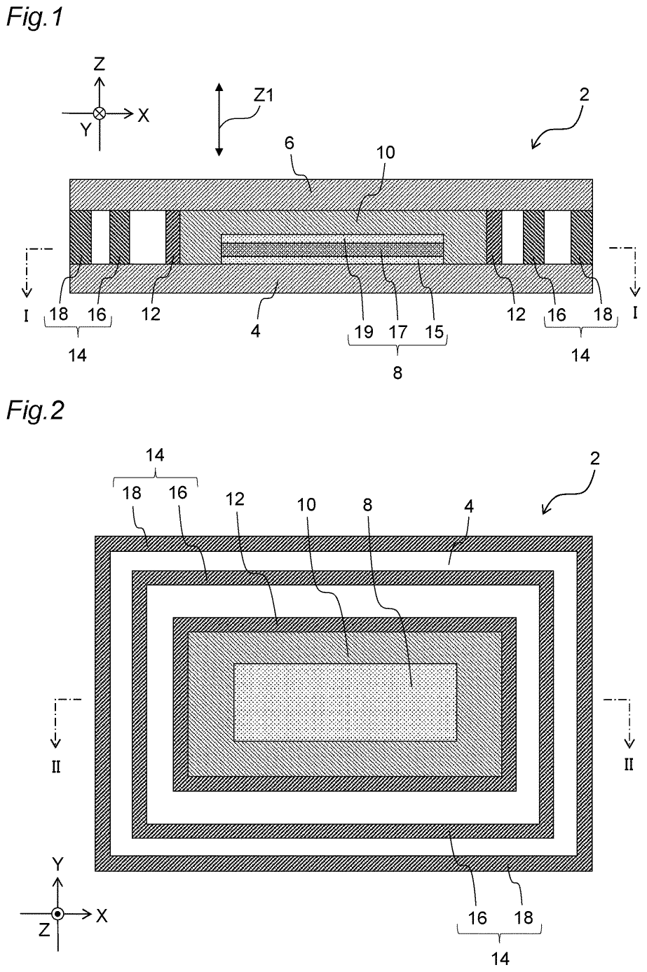

A power-generation module according to a first embodiment of the present disclosure will be described with reference to FIGS. 1 and 2.

FIG. 1 is a longitudinal cross-sectional view (cross-sectional view taken along line II-II in FIG. 2) of a power-generation module 2 according to the first embodiment of the present disclosure, and FIG. 2 is a transverse cross-sectional view (cross-sectional view taken along line I-I in FIG. 1) of the power-generation module 2.

For convenience of explanation, an XYZ Cartesian coordinate system is shown in the drawings, but this coordinate system is intended to facilitate understanding of the present disclosure and does not limit the present disclosure.

The power-generation module 2 shown in FIGS. 1 and 2 is a module used for photovoltaic power generation. The power-generation module 2 can be used, for example, as a solar cell module for building integrated photovoltaics (BIPV) or a general solar cell module other than BIPV (for example, a silicon-based solar cell module sandwiched between glass substrates). It can also be used in BIPV using silicon-based solar cells.

The power-generation module 2 is applicable to, for example, modules and BIPVs using silicon solar cells, and modules and BIPVs using perovskite solar cells.

The power-generation module 2 used as BIPV also functions as a building material for roofs, walls, windows, etc. The building material constitutes at least a part of, for example, a building, a vehicle, etc.

The power-generation module 2 includes a first substrate 4, a second substrate 6, a photovoltaic cell 8, an intermediate film 10, an internal sealing member 12, and an external sealing member 14.

The first substrate 4 and the second substrate 6 are each a member that forms the outer casing of the power-generation module 2. The first substrate 4 and the second substrate 6 are each a plate-shaped member that has a thickness direction Z1 coinciding with the Z-axis direction and that extends in an XY plane orthogonal to the thickness direction Z1. The first substrate 4 and the second substrate 6 are disposed facing each other in the thickness direction Z1, with the photovoltaic cell 8 and the intermediate film 10 interposed therebetween.

The first substrate 4 and the second substrate 6 are each made of a material with low moisture and gas permeability so as to prevent deterioration due to moisture and gas. The material is, for example, resin or glass.

In this embodiment, both the first substrate 4 and the second substrate 6 are made of transparent glass plates and have light-transmitting properties. The first substrate 4 may be an opaque substrate, as long as at least the second substrate 6 has light-transmitting properties that allow light to enter the photovoltaic cell 8 from outside the power-generation module 2.

In the following description, for convenience, the direction from the first substrate 4 to the second substrate 6 (+Z direction) will be referred to as the upward direction, and the direction from the second substrate 6 to the first substrate 4 (−Z direction) will be referred to as the downward direction.

In this embodiment, the distance between the first substrate 4 and the second substrate 6 in the thickness direction Z1 is 0.5 mm or more and 3 mm or less. While this short distance between the first substrate 4 and the second substrate 6 allows for size reduction and cost reduction, it also requires a smaller nozzle diameter for applying the sealing members 12 and 14, which can make it difficult to ensure a sufficient amount of material, potentially reducing sealability. In this embodiment, by arranging two layers of the external sealing members 16 and 18 while using a reduced-diameter nozzle, the power-generation module 2 with improved sealability is implemented. Details will be described later.

As shown in FIG. 1, the photovoltaic cell 8, the intermediate film 10, the inner sealing member 12, and the outer sealing member 14 are arranged between the first substrate 4 and the second substrate 6.

The photovoltaic cell 8 is a cell for converting the optical energy of light incident on the power-generation module 2 into electrical energy. The photovoltaic cell 8 has a first electrode layer 15, a semiconductor layer 17, and a second electrode layer 19, and has a stacked structure in which the first electrode layer 15, the semiconductor layer 17, and the second electrode layer 19 are stacked in the mentioned order in the thickness direction Z1.

The first electrode layer 15 and the second electrode layer 19 are layers electrically connected to the semiconductor layer 17, and the semiconductor layer 17 has a function of converting light energy into electrical energy.

The first electrode layer 15 is stacked on the upper main surface of the first substrate 4, the semiconductor layer 17 is stacked on the upper main surface of the first electrode layer 15, and the second electrode layer 19 is stacked on the upper main surface of the semiconductor layer 17.

The first electrode layer 15 and the second electrode layer 19 are transparent electrodes containing, for example, fluorine-doped tin oxide (FTO), indium oxide (IO), indium zinc oxide (IZO), tin oxide, zinc oxide, aluminum zinc oxide (AZO), etc. In this embodiment, the first electrode layer 15 is a transparent electrode containing fluorine-doped tin oxide, and the second electrode layer 19 is a transparent electrode containing indium oxide.

The material for the semiconductor layer 17 includes, for example, single crystal silicon, polycrystalline silicon, amorphous silicon, microcrystalline silicon, a compound semiconductor, and an organic semiconductor. In this embodiment, the semiconductor layer 17 has a stacked structure in which a p-type semiconductor, an intrinsic semiconductor including perovskite crystals (perovskite material), and an n-type semiconductor are stacked. Furthermore, the semiconductor layer 17 may further include a layer for protecting these semiconductors and a layer for transporting charges or holes.

A pair of lead wires not shown are connected to the photovoltaic cell 8. One lead wire is connected to the first electrode layer 15, and the other lead wire is connected to the second electrode layer 19. The pair of lead wires pass through the intermediate film 10 and the sealing members 12, 14 and are drawn out to the outside of the power-generation module 2. Outside the power-generation module 2, each lead wire is connected, for example, to a controller (not shown) that controls power generation and distributes the generated power, or to a terminal disposed on a terminal box. Each lead wire functions as wiring that extracts the power generated by the photovoltaic cell 8 to the outside of the power-generation module 2.

In the example shown in FIGS. 1 and 2, only one photovoltaic cell 8 is shown, but a plurality of solar cells may be disposed connected in parallel.

The interlayer film 10 is a member disposed so as to cover the photovoltaic cell 8 from above, and prevents gas or liquid from entering the photovoltaic cell 8. A power-generation module structure having the interlayer film 10 may be referred to as a “laminated glass structure.”

The intermediate film 10 has a thickness significantly greater than that of the photovoltaic cell 8 (for example, about 1000 times greater), and has a sheet-like shape that extends longitudinally in the XY plane. The intermediate film 10 is made of a soft material, and is in intimate contact with the photovoltaic cell 8 from above.

Sealing members 12 and 14 are arranged around the photovoltaic cell 8 and the intermediate film 10 to seal the space between the first substrate 4 and the second substrate 6. By arranging the sealing members 12 and 14 in addition to the intermediate film 10, it is possible to further prevent gas or liquid from entering the photovoltaic cell 8, and improve the durability and lifespan of the power-generation module 2 including the photovoltaic cell 8.

As shown in FIG. 2, the sealing members 12 and 14 each have an annular shape surrounding the photovoltaic cell 8 and the intermediate film 10 in a plan view seen from the Z-axis direction.

The sealing members 12, 14 of this embodiment include an inner sealing member 12 and an outer sealing member 14.

The internal sealing member 12 is a sealing member that is positioned surrounding the outer periphery of the photovoltaic cell 8, and the external sealing member 14 is a sealing member that is placed outside the internal sealing member 12 with a space therebetween.

The internal sealing member 12 is made of a material that mainly functions to prevent oxygen from entering the sealing member 12. The material for the internal sealing member 12 is, for example, ethylene vinyl alcohol copolymer resin (EVOH).

The external sealing member 14 is made of a material that mainly functions to prevent water vapor from entering the sealing member 14. The material for the external sealing member 14 is, for example, butyl rubber.

As described above, the inner sealing member 12 and the outer sealing member 14 are made of different types of materials so as to prevent the intrusion of different objects.

In this embodiment, the inner sealing member 12 is disposed in only one layer, and the outer sealing member 14 is disposed in plural layers (two layers in this embodiment).

In the example shown in FIG. 2, the internal sealing member 12 is disposed in contact with the outer periphery of the intermediate film 10, but this is not limitative and the internal sealing member 12 may be spaced apart from the outer periphery of the intermediate film 10.

The external sealing member 14 has an inner first sealing member 16 and an outer second sealing member 18. In the example shown in FIG. 2, the first sealing member 16 is disposed outside the internal sealing member 12 with a space therebetween, and the second sealing member 18 is disposed outside the first sealing member 16 with a space therebetween. In the example shown in FIG. 2, the internal sealing member 12 is disposed in contact with the outer periphery of the intermediate film 10, but this is not limitative and the internal sealing member 12 may be spaced apart from the outer periphery of the intermediate film 10.

By arranging plural layers of the external sealing member 14, it is possible to improve the function of inhibiting the intrusion of mainly water vapor. The first sealing member 16 and the second sealing member 18 are made of the same material, such as butyl rubber, and have the same function of inhibiting the intrusion of mainly water vapor. In particular, the intrusion inhibition function (mainly water vapor) provided by the external sealing member 14 tends to be weaker than the intrusion inhibition function (mainly oxygen) provided by the internal sealing member 12, and therefore, by arranging plural layers of the external sealing member 14, it is possible to effectively improve the durability of the power-generation module 2 including the photovoltaic cell 8.

On the other hand, it is also possible to arrange plural layers of the internal sealing member 12. The nozzle used to dispense the internal sealing member 12 needs to be longer than the nozzle used to dispense the external sealing member 14, making it difficult to ensure a sufficient amount of material is dispensed. In such a case, arranging plural layers of the internal sealing member 12, like the external sealing member 14, can further improve the durability of the power-generation module 2 including the photovoltaic cell 8.

In this embodiment, in the process of arranging plural layers of external sealing members 14, an coating device having two discharge ports is used to simultaneously form the first sealing member 16 and the second sealing member 18. This makes it possible to easily form two layers of external sealing members 14, thereby improving the efficiency of the manufacturing process for the power-generation module 2.

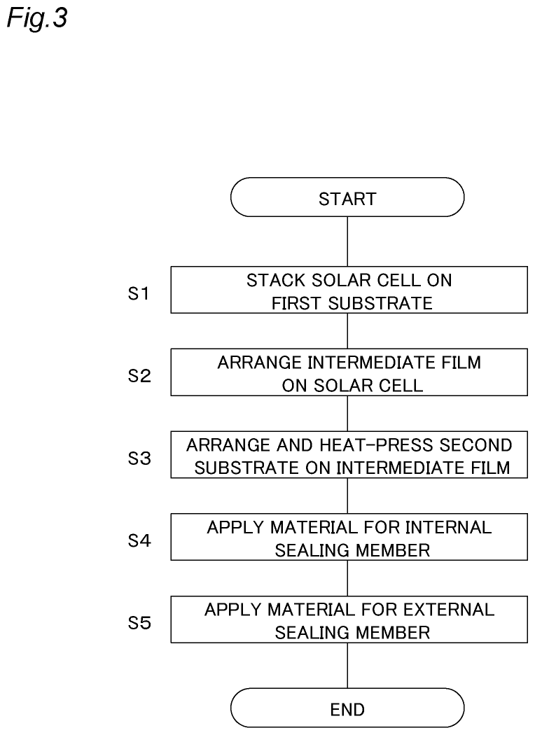

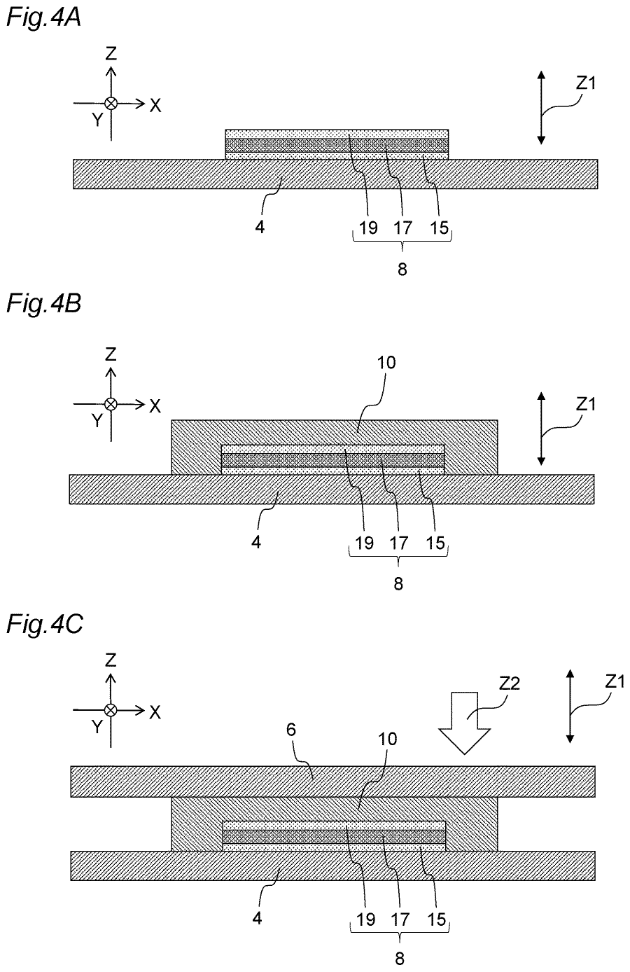

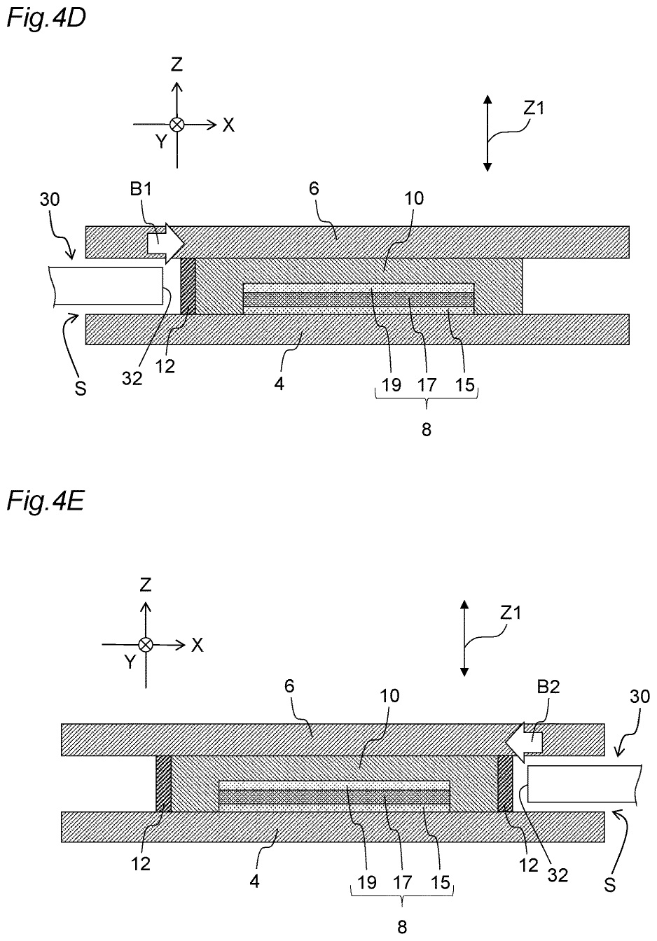

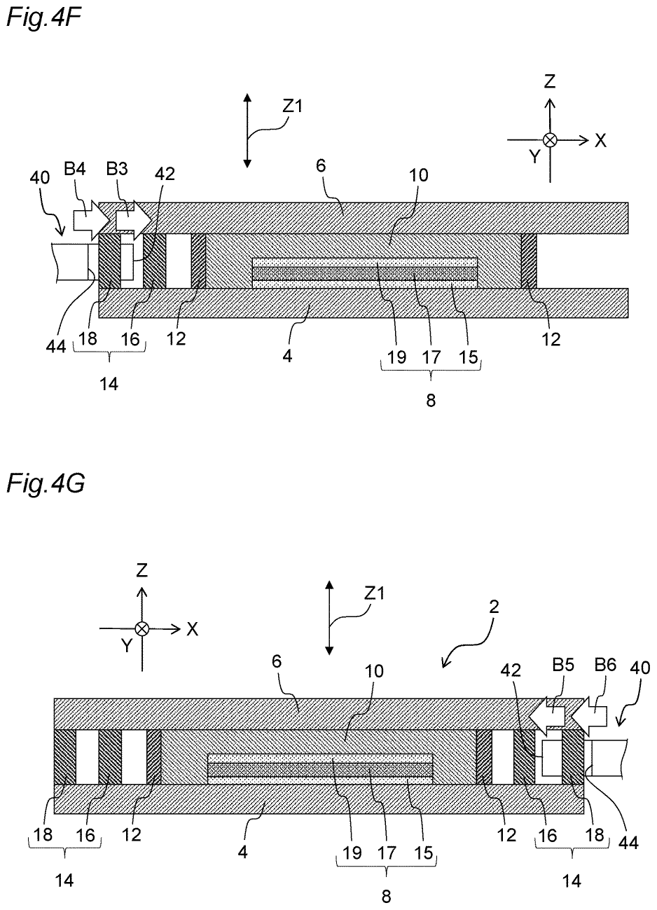

The overview of the method for manufacturing the power-generation module 2 shown in FIGS. 1 and 2 will be described with reference to FIGS. 3 and 4A to 4G.

FIG. 3 is a flowchart showing the flow of a method for manufacturing the power-generation module 2 shown in FIGS. 1 and 2, and FIGS. 4A to 4G are schematic longitudinal cross-sectional views for explaining the method for manufacturing the power-generation module 2 according to the flowchart of FIG. 3.

First, the photovoltaic cell 8 is stacked on the first substrate 4 (S1). Specifically, as shown in FIG. 4A, the first substrate 4 is placed horizontally, and the photovoltaic cell 8 is stacked on the upper main surface of the first substrate 4. Of the photovoltaic cell 8, the first electrode layer 15, the semiconductor layer 17, and the second electrode layer 19 are stacked in the mentioned order.

The first electrode layer 15 is stacked on the first substrate 4 by various methods, such as vapor deposition, sputtering, spin coating, inkjet printing, etc. In a similar manner, the semiconductor layer 17 is stacked on the first electrode layer 15, and the second electrode layer 19 is stacked on the semiconductor layer 17.

As shown in FIG. 4B, the intermediate film 10 is arranged on the photovoltaic cell 8 (S2). The intermediate film 10 is a soft sheet-like member that is thicker than the photovoltaic cell 8 and has larger dimensions in the XY plane, and covers the entire photovoltaic cell 8. When a plurality of solar cells 8 are disposed, an intermediate film having a size that covers the entire photovoltaic cell 8 may be used.

As shown in FIG. 4C, the second substrate 6 is arranged on the intermediate film 10 and is heat-pressed in the Z-axis direction (arrow Z2) (S3). The intermediate film 10 melts when heated and adheres tightly to the photovoltaic cell 8 so as to eliminate any spaces between the intermediate film 10 and the outer periphery of the photovoltaic cell 8.

As shown in FIG. 4D, a material for the internal sealing material 12 is applied (S4). Specifically, an coating device 30, which will be described later, is used to apply the material for the internal sealing material 12 to the periphery of the photovoltaic cell 8 and the intermediate film 10. The nozzle of the coating device 30 is inserted into the space S between the first substrate 4 and the second substrate 6, and the coating device 30 is swept in a predetermined direction (for example, the Y direction), so that the material for the internal sealing material 12 is applied through a discharge port 32 disposed at the tip of the nozzle, and then cured.

As shown in FIG. 2, each side of the internal sealing member 12 is formed in order so that the internal sealing member 12 has plural sides (four sides in this embodiment). Specifically, as shown in FIG. 4D, one side of the internal sealing member 12 is formed using the coating device 30 (arrow B1), and then, as shown in FIG. 4E, a different side of the internal sealing member 12 is formed using the same coating device 30 (arrow B2). By forming the four sides in order, the internal sealing member 12 is formed in a rectangular shape in plan view.

As shown in FIG. 4F, the material for the external sealing member 14 is applied (S5). Specifically, an coating device 40 (described later) is used to form the first sealing member 16 and the second sealing member 18 as the external sealing member 14 around the internal sealing member 12. The coating device 40 is different from the coating device 30 shown in FIGS. 4D and 4E and has two dispensing ports 42, 44 at the tip of its nozzle. The nozzle of the coating device 40 is inserted into the space S between the first substrate 4 and the second substrate 6, and the coating device 40 is swept in a predetermined direction (e.g., the Y direction) to apply the material for the first sealing member 16 through a dispensing port 42 and apply the material for the second sealing member 18 through a dispensing port 44. This allows the material for the first sealing member 16 and the second sealing member 18 to be applied simultaneously, making it easy to form plural layers of the external sealing member 14.

As shown in FIG. 2, each side of the external sealing member 14 is formed in order so that the external sealing member 14 has plural sides (four sides in this embodiment) similar to the internal sealing member 12. Specifically, as shown in FIG. 4F, one side of each of the first sealing member 16 and the second sealing member 18 is formed using the coating device 40 (arrows B3 and B4), and then, as shown in FIG. 4G, the same coating device 40 is used to form different sides of each of the first sealing member 16 and the second sealing member 18 (arrows B5 and B6). By forming the four sides in order, the external sealing member 14 is formed in a rectangular shape in plan view.

By executing the above steps S1 to S5, it is possible to manufacture the power-generation module 2 having one layer of internal sealing member 12 and plural layers (two layers in this embodiment) of external sealing member 14, as shown in FIGS. 1 and 2.

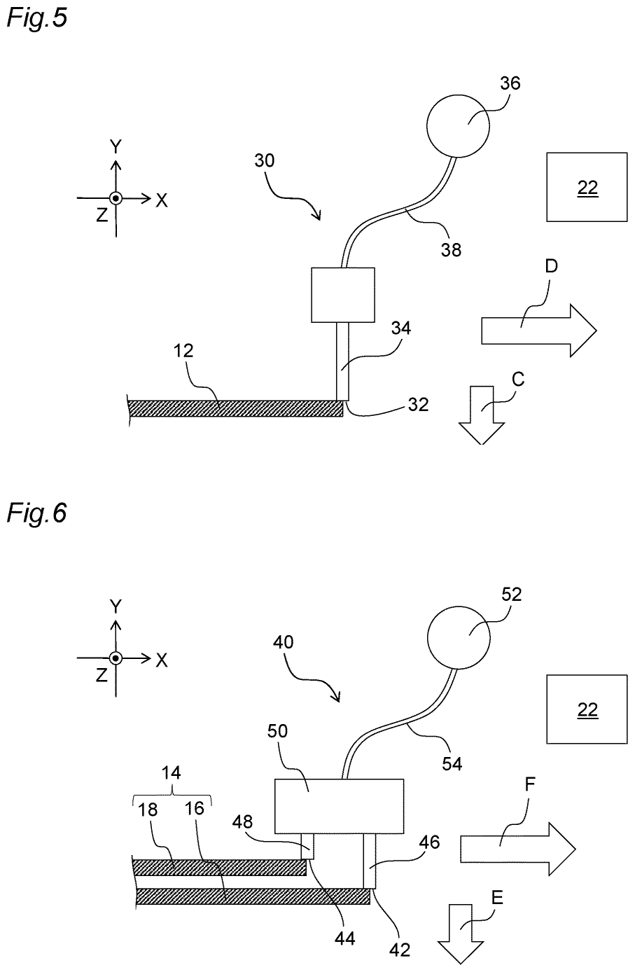

Next, the specific configurations of the coating devices 30 and 40 will be described with reference to FIGS. 5 and 6.

FIG. 5 is a plan view schematically showing the coating device 30 for the internal sealing member, and FIG. 6 is a plan view schematically showing the coating device 40 for the external sealing member.

The coating device 30 shown in FIG. 5 has one nozzle 34 having one dispensing port 32, a supply source 36, and a supply member 38.

The nozzle 34 is a member having the dispensing port 32 at its tip, and is connected to the supply source 36 by the supply member 38. The supply source 36 is a portion that holds the raw material (e.g., EVOH) for the internal sealing member 12, and the material for the internal sealing member 12 is supplied to the dispensing port 32 of the nozzle 34 via the supply member 38.

The coating device 30 shown in FIG. 5 is connected to a control unit 22, which controls the operation of the coating device 30. The control unit 22 is configured with, for example, a microcomputer including a processor and a memory that stores a computer program executed by the processor.

The nozzle 34 extends in a predetermined direction C, and the control unit 22 controls the nozzle 34 to sweep along a sweep direction D that intersects with the predetermined direction C and to dispense the material for the internal sealing member 12 through the dispensing port 32. In this way, the material for the internal sealing member 12 can be applied along the sweep direction D of the nozzle 34.

The coating device 30 shown in FIG. 5 further includes a mechanism (for example, an XY two-axis stage) for rotating the nozzle 34 in the XY plane, thereby enabling the orientation of the nozzle 34 to be changed.

The coating device 40 shown in FIG. 6 includes two nozzles 46 and 48 having two dispensing ports 42 and 44, a buffer unit 50, a supply source 52, and a supply member 54.

The first nozzle 46 is a nozzle having the first dispensing port 42 at its tip, and the second nozzle 48 is a nozzle having the second dispensing port 44 at its tip. The buffer unit 50 is a member that enables the supply of material for the external sealing member 14 to the two nozzles 46, 48, and holds the two nozzles 46, 48 together. The buffer unit 50 in this embodiment functions as a connecting unit that connects the two nozzles 46, 48 to each other.

The supply source 52 is a section that holds the raw material (e.g., butyl rubber) for the external sealing member 14, and the material for the external sealing member 14 is supplied to the buffer section 50 via the supply member 54.

According to the above configuration, the same type of raw material can be simultaneously supplied from the common supply source 52 to the two dispensing ports 42 and 44.

The coating device 40 shown in FIG. 6 is connected to the control unit 22, and the control unit 22 controls the operation of the coating device 40.

The nozzles 46, 48 each extend in a predetermined direction E, and the control unit 22 controls the nozzles 46, 48 and the buffer unit 50 to sweep along a sweep direction F that intersects with the predetermined direction E, thereby dispensing the material for the first sealing member 16 through the first dispensing port 42 and dispensing the material for the second sealing member 18 through the second dispensing port 44. This allows two layers of the external sealing member 14 to be formed simultaneously along the sweep direction F.

As shown in FIG. 6, the two dispensing ports 42, 44 are positioned differently in the predetermined direction E. Specifically, the first dispensing port 42 is located on the distal side in the predetermined direction E relative to the second dispensing port 44. The first nozzle 46 and the second nozzle 48 are spaced apart in a direction (sweep direction F) intersecting the predetermined direction E, and when the coating device 40 is swept, the first nozzle 46 having the first dispensing port 42 lies downstream of the second nozzle 48 having the second dispensing port 44 in the sweep direction F. This allows the two nozzles 46, 48 to simultaneously apply the material for two layers of the external sealing member 14 along the sweep direction F without interfering with the material for the external sealing member 14 that has already been applied.

By using the buffer unit 50 connecting the two nozzles 46, 48, it becomes easier to move the nozzles 46, 48 together and to apply the material for the sealing members 16, 18 to the desired positions.

The coating device 40 shown in FIG. 6 further includes a mechanism (for example, an XY two-axis stage) for integrally rotating the nozzles 46, 48 and the buffer unit 50 within the XY plane. This allows the orientation of the nozzles 46, 48 to be changed.

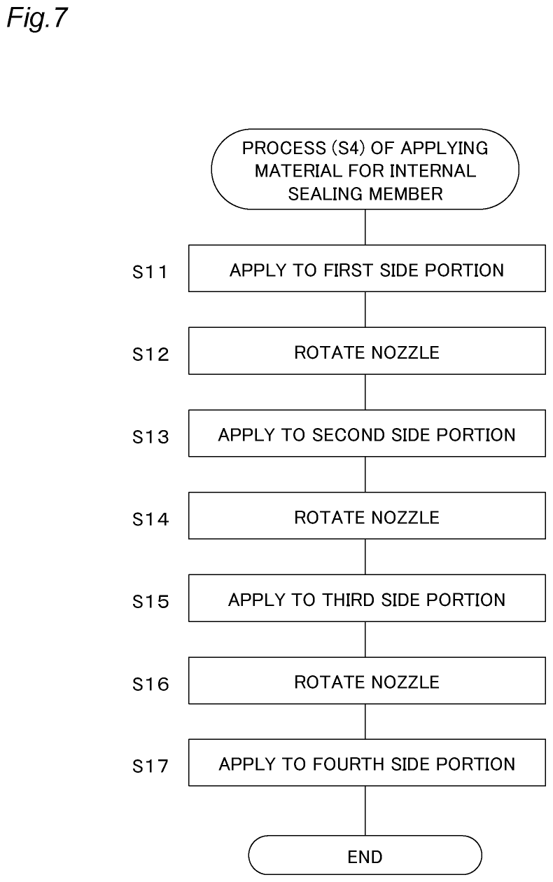

Specific methods for applying the material for the internal sealing member 12 and the external sealing member 14 using the above two types of coating devices 30 and 40 will be described with reference to FIGS. 7, 8A, 8B, 9, and 10A to 10J.

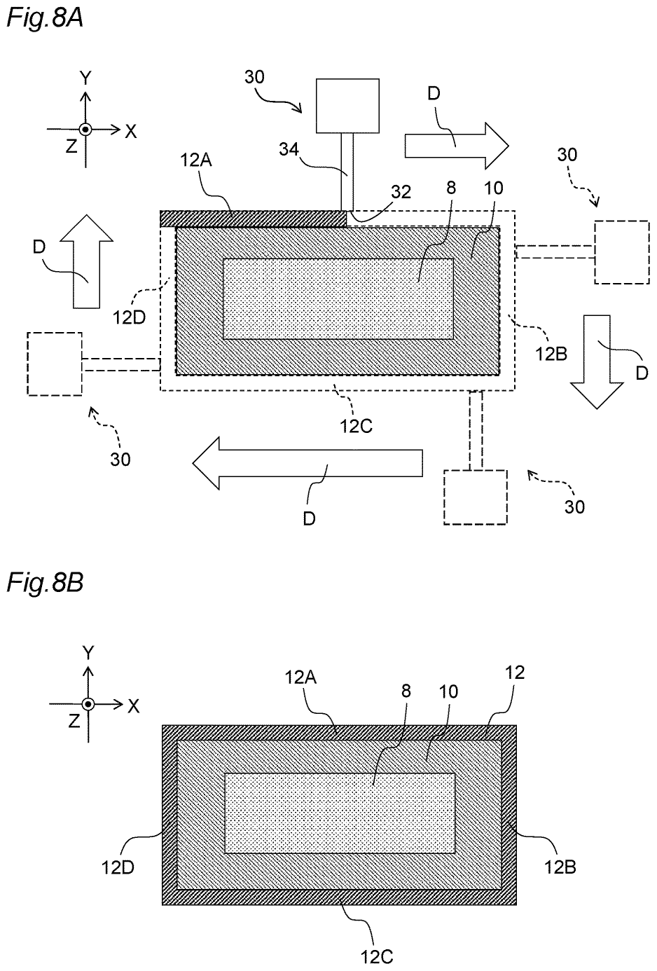

FIG. 7 is a flowchart showing the flow of the process (step S4) of applying the material for the internal sealing member 12, and FIGS. 8A and 8B are schematic transverse cross-sectional views for explaining the application process according to the flowchart of FIG. 7.

First, the material for the internal sealing member 12 is applied to a first side 12A portion (S1). Specifically, as shown in FIG. 8A, the coating device 30 is swept in the sweep direction D while the material for the internal sealing member 12 is dispensed through the dispensing port 32 of the nozzle 34 to form the first side 12A of the internal sealing member 12.

Subsequently, the nozzle 34 is rotated (S12). By rotating the nozzle 34 by approximately 90 degrees, the coating device 30 is swept in the sweep direction D orthogonal to the sweep direction D in step S1, thereby forming a different side of the internal sealing member 12. Instead of rotating the nozzle 34, the power-generation module 2 may also be rotated.

Thereafter, the material for the internal sealing member 12 is applied to a second side 12B portion using the coating device 30 (S13), the nozzle 34 is rotated approximately 90 degrees (S14), the material for the internal sealing member 12 is applied to a third side 12C portion (S15), the nozzle 34 is rotated approximately 90 degrees (S16), and the material for the internal sealing member 12 is applied to a fourth side 12D portion (S17).

As a result, as shown in FIG. 8B, the material for the internal sealing member 12 can be applied to the four annular side portions 12A to 12D around the photovoltaic cell 8 and the intermediate film 10.

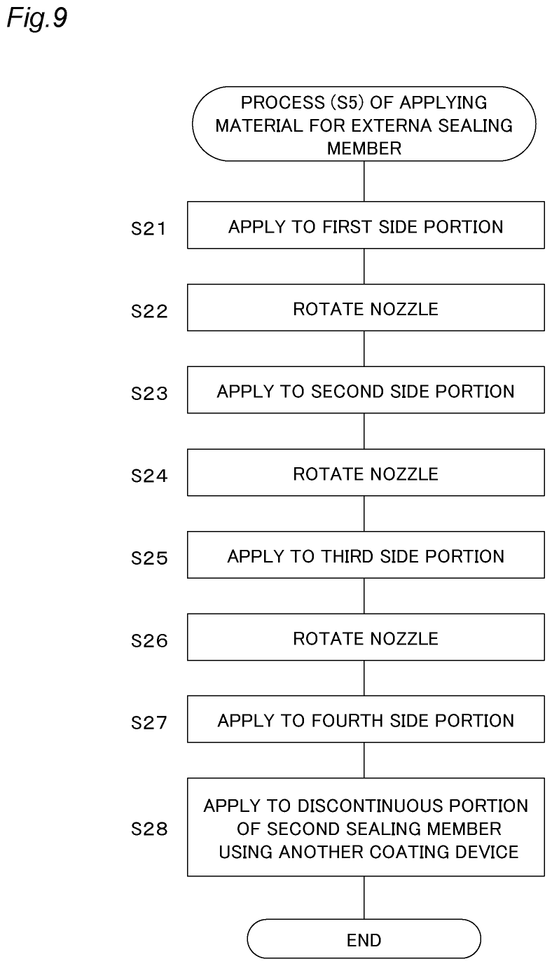

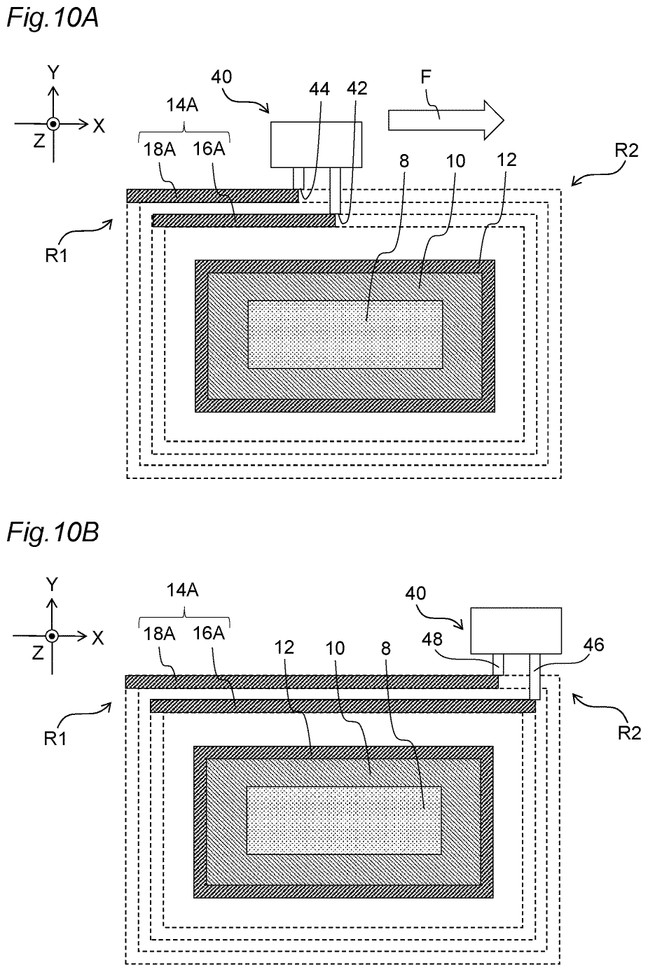

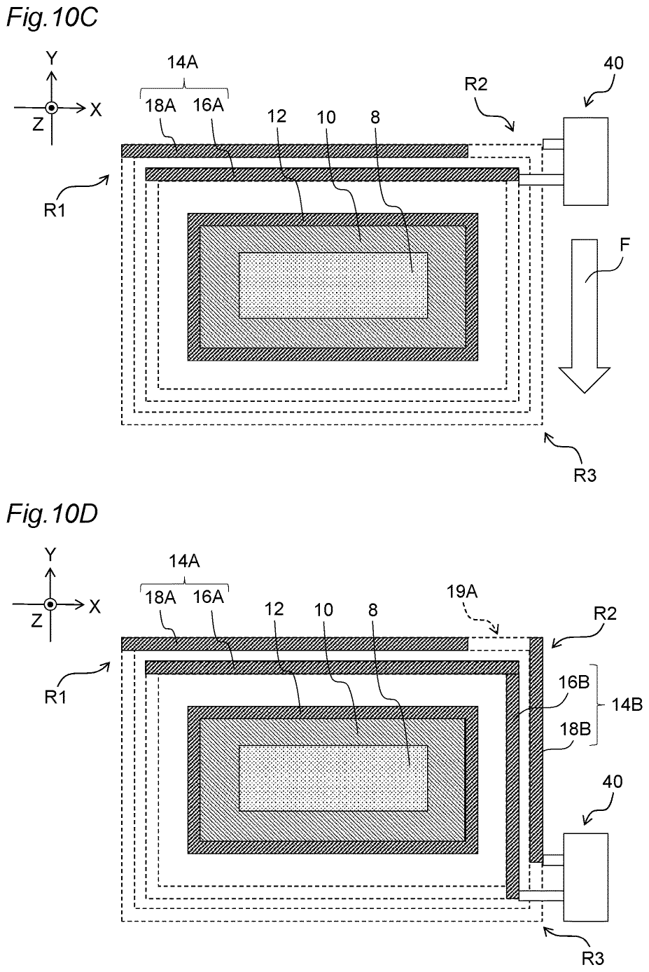

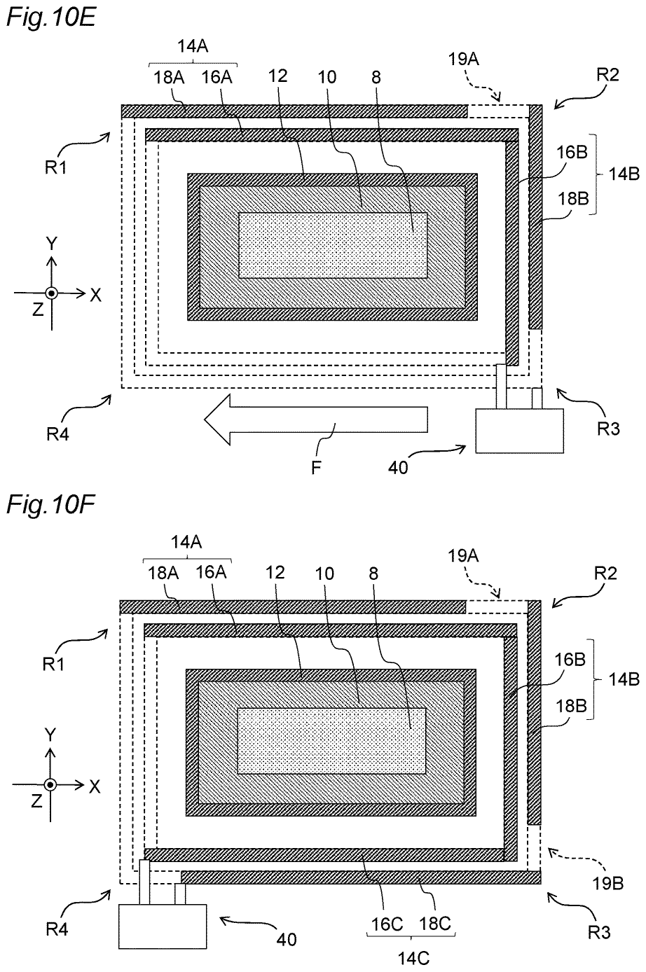

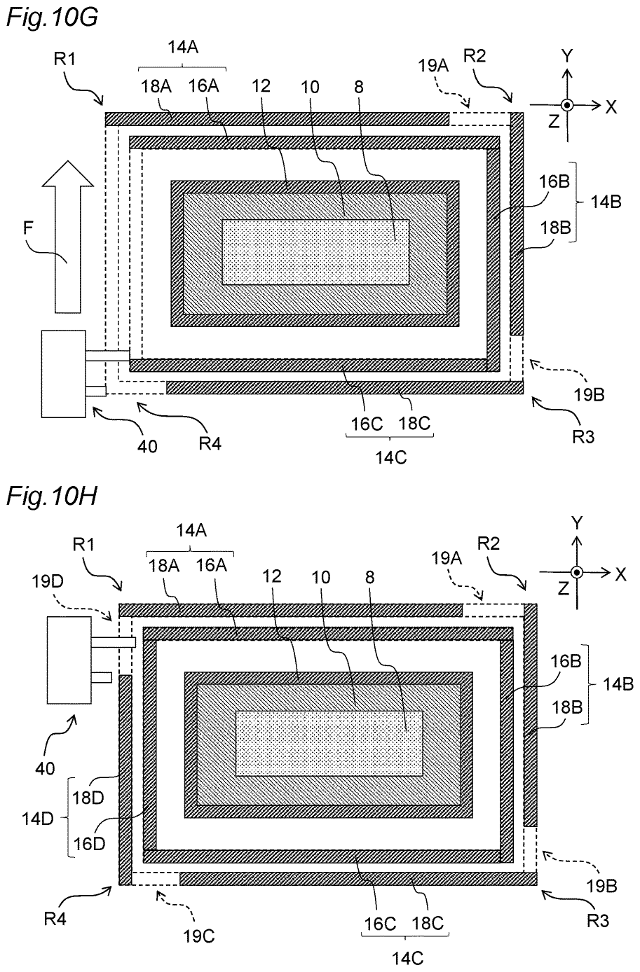

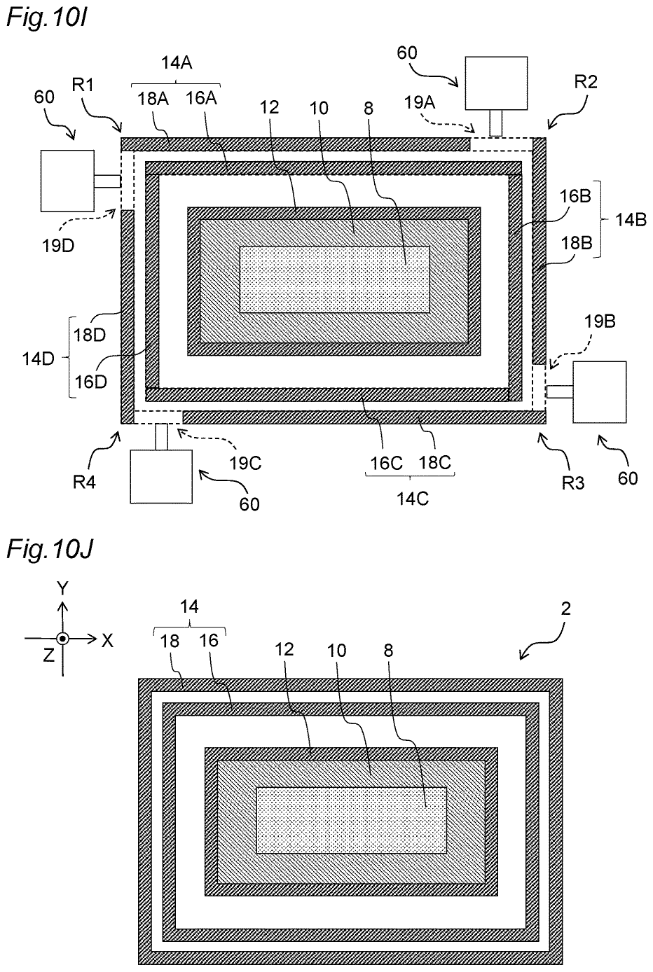

FIG. 9 is a flowchart showing the flow of the process (step S5) of applying the material for the external sealing member 14, and FIGS. 10A to 10J are schematic transverse cross-sectional views for explaining the application process according to the flowchart of FIG. 9.

First, the material for the external sealing member 14 is applied to a first side portion (S21). Specifically, as shown in FIG. 10A, the coating device 40 is swept in the sweep direction F from a corner R1 of the power-generation module 2 toward a corner R2 adjacent to the corner R1, while applying the material for the first sealing member 16 to a first side 16A portion from the first dispensing port 42 and applying the material for the second sealing member 18 to a first side 18A portion from the second dispensing port 44.

As shown in FIG. 10B, when the first side 16A of the first sealing member 16 reaches the corner R2, the sweeping and application of the coating device 40 is stopped, and the nozzles 46, 48 of the coating device 40 are rotated approximately 90 degrees (S22).

As shown in FIG. 10C, the coating device 40 is swept in the sweep direction F from the corner R2 toward an adjacent corner R3, thereby forming the second side 14B of the external sealing member 14 as shown in FIG. 10D (S23).

At the corner R2 shown in FIG. 10D, the first side 18A of the second sealing member 18 terminates short of the first side 16A of the first sealing member 16. A discontinuous portion 19A occurs between the first side 18A and the second side 18B, where the second sealing member 18 is discontinued.

When a second side 16B of the first sealing member 16 reaches the corner R3, the sweeping and application of the coating device 40 is stopped, and the nozzles 46, 48 are rotated approximately 90 degrees (S24).

As shown in FIG. 10E, the coating device 40 is swept in the sweep direction F from the corner R3 toward an adjacent corner R4, thereby forming a third side 14C of the external sealing member 14, as shown in FIG. 10F (S25). At the corner R3 shown in FIG. 10F, a discontinuous portion 19B occurs where the second sealing member 18 is interrupted.

When a third side 16C of the first sealing member 16 reaches the corner R4, the sweeping and application of the coating device 40 is stopped, and the nozzles 46, 48 are rotated approximately 90 degrees (S26).

As shown in FIG. 10G, the coating device 40 is swept in the sweep direction F from the corner R4 toward the adjacent corner R1, thereby forming a fourth side 14D of the external sealing member 14 as shown in FIG. 10H (S27). At the corner R4 shown in FIG. 10H, a discontinuous portion 19C occurs where the second sealing member 18 is interrupted, and at the corner R1, a discontinuous portion 19D occurs.

Afterward, an coating device different from the coating device 40 is used to apply the material for the second sealing member 18 to the discontinuous portions 19A to 19D (S28). Specifically, as shown in FIG. 10I, an coating device 60 having one dispensing port and one nozzle is used to apply the material for the second sealing member 18 to each of the discontinuous portions 19A to 19D. This allows the discontinuous portions 19A to 19D to be filled in and second sealing member 18 to be formed in an annular shape.

When applying to the four discontinuous portions 19A to 19D using the coating device 60, for example, the nozzle of the coating device 60 may be rotated appropriately while the orientation of the power-generation module 2 is fixed, and the coating device 60 may be swept in each predetermined direction. Alternatively, the orientation of the coating device 60 may be fixed, and the power-generation module 2 may be rotated appropriately, and the coating device 60 may be swept in a fixed direction.

By executing steps S21 to S28, a highly sealed power-generation module 2 can be manufactured, in which the external sealing member 14 having two layers of sealing members 16, 18 is arranged on the outside of the internal sealing member 12, as shown in FIG. 10J.

According to the manufacturing method of the power-generation module 2 of this embodiment, the steps of simultaneously applying to the portions of the two layers of sealing members 16, 18 (S21, S23, S25, S27) are performed, thereby improving the sealability of the power-generation module 2. Note that in the step of simultaneously applying to the portions of the two layers of sealing members 16, 18, simultaneous application is not always required, but may be carried out at least part of the time. In other words, when applying to the first sealing member 16 portion and the second sealing member 18 portion, the application of the adhesive need not start and end simultaneously.

According to the manufacturing method of the power-generation module 2 of this embodiment, two layers of sealing member 16, 18 are simultaneously formed using the coating device 40 having two dispensing ports 42, 44, thereby improving the sealability of the power-generation module 2 and streamlining the manufacturing process. Note that application is not limited to automatic application using the coating device 40, and may also be performed manually by an operator.

In particular, in this embodiment, since the distance between the first substrate 4 and the second substrate 6 in the thickness direction Z1 is short (for example, 0.5 mm to 3 mm), the diameter of the nozzle that applies the material for the sealing member needs to be small. In response to this, by applying to the portions of two layers of sealing members 16, 18 using the coating device 40 having two dispensing ports 42, 44 and two nozzles 46, 48, it becomes easier to ensure sufficient sealability while reducing the nozzle diameter.

When the power-generation module 2 is used as a perovskite solar cell, it is more susceptible to water vapor and oxygen than a typical silicon solar cell, and therefore the arrangement of two layers of sealing members 16, 18 as in this embodiment can have a significant effect in improving durability. This is more suitable for perovskite solar cells.

### Effects, etc.

The manufacturing method of the power-generation module 2 of the first embodiment is a method for manufacturing the power-generation module 2 in which the photovoltaic cell 8 and the sealing members 16, 18 are arranged between the first substrate 4 and the second substrate 6, wherein the first sealing member 16 is formed around the photovoltaic cell 8, and wherein the second sealing member 18 is formed outside of the first sealing member 16.

According to such a method, the sealability of the sealing members 16 and 18 can be improved.

In the manufacturing method of the power-generation module 2 of the first embodiment, when the material for the first sealing member 16 and the second sealing member 18 is applied in a predetermined direction (sweep direction F), the application position for the first sealing member 16 lies downstream in the predetermined direction from the application position for the second sealing member 18. This method allows the material for the two layers of sealing members 16, 18 to be applied efficiently.

In the manufacturing method of the power-generation module 2 of the first embodiment, the material for the first sealing member 16 and the second sealing member 18 is applied to form a plurality of sides of the power-generation module 2, and the material for the second sealing member 18 is further applied to positions (discontinuous portions 19A to 19D) where the second sealing member 18 is discontinued on two adjacent sides of the plurality of sides. According to this method, by applying the material for the second sealing member 18 to the discontinuous portions 19A to 19D of the second sealing member 18, the process of applying the material for the second sealing member 18 in an annular shape can be easily carried out.

In the manufacturing method of the power-generation module 2 of the first embodiment, the distance between the first substrate 4 and the second substrate 6 in the thickness direction Z1 of the power-generation module 2 is 3 mm or less. According to this method, when the distance between the first substrate 4 and the second substrate 6 is short, the diameter of the nozzle of the coating device becomes small, making it difficult to ensure a sufficient amount of application, whereas forming two layers of the sealing members 16, 18 makes it easier to ensure sufficient sealability.

In the manufacturing method of the power-generation module 2 of the first embodiment, the first sealing member 16 and the second sealing member 18 contain materials having the same function. According to this method, the sealability of the sealing members 16 and 18 can be improved.

In the manufacturing method of the power-generation module 2 of the first embodiment, the material having the same function mainly has the function of suppressing the intrusion of water vapor. According to such a method, it is possible to improve the effect of suppressing the intrusion of water vapor.

In the manufacturing method of the power-generation module 2 of the first embodiment, the first sealing member 16 and the second sealing member 18 are simultaneously formed. This method improves the sealability and makes the manufacturing process of the power-generation module 2 more efficient.

In addition, the coating device 40 of the first embodiment described above has the first dispensing port 42 that dispenses the material for the first sealing member 16 and the second dispensing port 44 that dispenses the material for the second sealing member 18 so that the first sealing member 16 and the second sealing member 18 outside the first sealing member 16 can be formed around the photovoltaic cell 8 between the first substrate 4 and the second substrate 6 of the power-generation module 2.

With such a configuration, the sealability of the sealing members 16 and 18 can be improved, and the manufacturing process of the power-generation module 2 can be made more efficient.

The coating device 40 of the first embodiment further includes the first nozzle 46 having the first dispensing port 42 and the second nozzle 48 having the second dispensing port 44. According to this method, use of the two nozzles 46, 48 enables flexible change in the design of the coating device 40, such as facilitating the adjustment of the positions of the two dispensing ports 42.

In the coating device 40 of the first embodiment, the first nozzle 46 and the second nozzle 48 each extend in the predetermined direction E (first direction), the first dispensing port 42 is spaced apart from the second dispensing port 44 in the predetermined direction E, and when forming the first sealing member 16 and the second sealing member 18, the first nozzle 46 and the second nozzle 48 are swept in the sweep direction F (second direction) that intersects with the predetermined direction E. According to this method, by locating the first dispensing port 42 on the distal side relative to the second dispensing port 44, the first sealing member 16 and the second sealing member 18 can be formed at desired positions.

In the coating device 40 of the first embodiment, when the first nozzle 46 and the second nozzle 48 are swept in the sweep direction F (second direction), the first nozzle 46 is positioned downstream of the second nozzle 48 in the sweep direction F (second direction). According to this method, interference between the nozzles 46, 48 and the sealing members 16, 18 can be prevented when the coating device 40 is swept.

The coating device 40 of the first embodiment further includes the buffer unit 50 (connecting unit) that connects and integrates the first nozzle 46 and the second nozzle 48. According to this method, it becomes easier to move the first nozzle 46 and the second nozzle 48 together when sweeping the coating device 40, making it easier to form the sealing members 16, 18 at desired positions.

The coating device 40 of the first embodiment supplies the material for the first sealing member 16 and the second sealing member 18 to each of the first dispensing port 42 and the second dispensing port 44 from the common supply source 52. According to this method, the same type of material for the sealing members can be supplied to the two dispensing ports 42, 44, which leads to cost reduction.

Furthermore, the power-generation module of the first embodiment described above comprises: the first substrate 4 and the second substrate 6 that are spaced apart from each other in the thickness direction Z1; the photovoltaic cell 8 arranged between the first substrate 4 and the second substrate 6; and the sealing members 12, 14 arranged around the photovoltaic cell 8, the sealing members 12, 14 including the internal sealing member 12 and the external sealing member 14 arranged outside the internal sealing member 12, the internal sealing member 12 and the external sealing member 14 being made of different types of material, the external sealing member 14 being disposed in plural layers when viewed from the thickness direction Z1.

With such a configuration, the sealability of the sealing members 16 and 18 can be improved.

### Variant of First Embodiment

In the first embodiment, the coating device 40 has been described as having the buffer unit 50, but the present invention is not limited to such a configuration, and any coating device having two dispensing ports may be used.

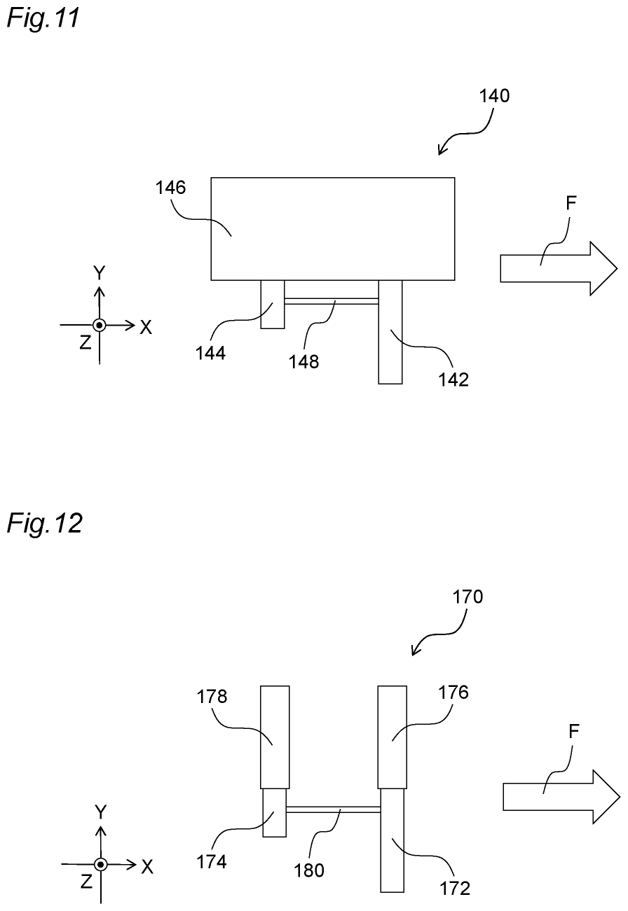

For example, an coating device 140 shown in FIG. 11 has two nozzles 142 and 144, a common dispense source 146, and a connection 148 that connects the two nozzles 142 and 144 to each other.

According to the configuration shown in FIG. 11, by disposing the connection 148 in addition to the dispense source 146 with the configuration simplified, the integrity of the coating device 140 can be enhanced, and the material for two layers of sealing members can be applied with high precision when the coating device 140 is swept in the sweep direction F.

For example, an coating device 170 shown in FIG. 12 has two nozzles 172 and 174, two dispense sources 176 and 178, and a connection 180.

The first dispense source 176 supplies a sealing material to the first nozzle 172, and the second dispense source 178 supplies a sealing material to the second nozzle 174. This makes it possible to supply different types of sealing materials to the two nozzles 172, 174.

According to the configuration shown in FIG. 12, the two nozzles 172, 174 have their respective dispense sources 176, 178, which enables the supply of the same or different types of sealing materials, and the connection 180 is disposed to connect the two nozzles 172, 174, which enables the materials for two layers of sealing members to be applied with high precision when the coating device 170 is swept in the sweep direction F.

### Second Embodiment

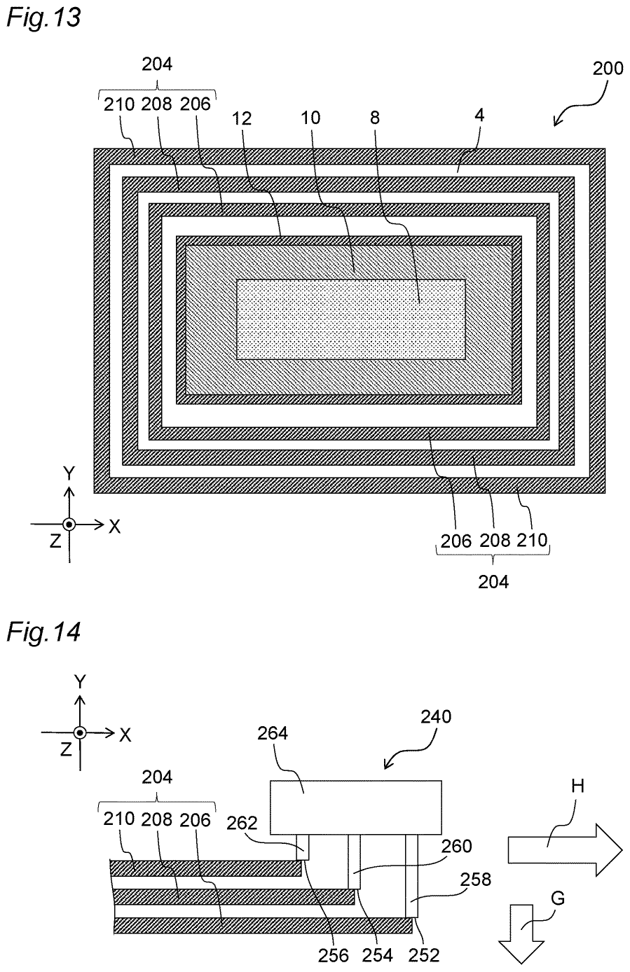

A power-generation module 200 and an coating device 240 according to a second embodiment of the present disclosure will be described with reference to FIGS. 13 and 14.

FIG. 13 is a transverse cross-sectional view schematically showing the power-generation module 200 according to the second embodiment of the present disclosure, and FIG. 14 is a plan view schematically showing the coating device 240 for applying a sealing material to the power-generation module 200 shown in FIG. 13.

The power-generation module 200 according to the second embodiment differs from the power-generation module 2 according to the first embodiment in that the external sealing member 204 is disposed in three layers instead of two layers. In the following description, the same reference numerals are used to designate components similar to those in the power-generation module 2, and descriptions thereof may be omitted.

As shown in FIG. 13, the power-generation module 200 has three layers of sealing members 206, 208, and 210 as the external sealing member 204.

The first sealing member 206 is the innermost layer, the second sealing member 208 is the intermediate layer, and the third sealing member 210 is the outermost layer. By arranging three layers of sealing members 206, 208, and 210 as the external sealing member 204, it is possible to further improve the sealability compared to when only two layers are disposed.

As shown in FIG. 14, the coating device 240 has three dispensing ports 252, 254, and 256, three nozzles 258, 260, and 262, and a buffer unit 264.

The first dispensing port 252 is disposed at the tip of the first nozzle 258, the second dispensing port 254 is disposed at the tip of the second nozzle 260, and the third dispensing port 256 is disposed at the tip of the third nozzle 262. The three nozzles 258, 260, 262 each extend in the predetermined direction G, and the first discharge port 252, the second discharge port 254, and the third discharge port 256 are located, in this order, toward the distal side in the predetermined direction G.

The buffer unit 264 holds and connects the three nozzles 258, 260, and 262, and the same type of material for the sealing member is supplied from a common dispense source not shown to the buffer unit 264. When the coating device 240 applies the sealing material, the same type of material for the sealing member can be applied simultaneously from the three dispensing ports 252, 254, and 256.

When the coating device 240 sweeps in a sweep direction H intersecting the predetermined direction G, the first nozzle 258 of the three nozzles 258, 260, 262 is positioned at the most downstream side during the sweeping, and the sealing material is dispensed from each of the three dispensing ports 252, 254, 256. This allows the first sealing member 206 to be formed as the innermost layer, the second sealing member 208 to be formed as the intermediate layer, and the third sealing member 210 to be formed as the outermost layer.

When forming the external sealing member 204 shown in FIG. 13 using the coating device 240 shown in FIG. 14, the application process: S21 to S28 in the flowchart of the first embodiment shown in FIG. 9 can be performed in the same manner.

In the coating device 240 shown in FIG. 14, discontinuous portions occur in the second sealing member 208 and the third sealing member 210, so that when applying to the discontinuous portions using a different coating device (step S28), the sealing material is applied to each of the discontinuous portion of the second sealing member 208 and the discontinuous portion of the third sealing member 210.

As described above, by adjusting the numbers of the dispensing ports and the nozzles of the coating device, it is possible to arrange three or more layers of external sealing members, not just two. Generally speaking, an coating device having the first dispensing port for dispensing the material for the first sealing member to an Nth dispensing port for dispensing the material for an Nth sealing member (N≥2) can be used to simultaneously apply the material for the first to Nth sealing members around the photovoltaic cell 8 in order from the inside out, thereby forming an N-layer sealing structure.

### Other Variants

The present disclosure has been described hereinabove with reference to the first and second embodiments described above, but the present disclosure is not limited to the above first and second embodiments. For example, in the first and second embodiments, the case of a “laminated glass structure” having the intermediate film 10 disposed around the photovoltaic cell 8 has been described, but the present disclosure is not limited to such a case, and a “double-glazed glass structure” not having the intermediate film 10 may also be used.

In the first and second embodiments, the case has been described where the photovoltaic cell 8 is stacked directly on the main surface of the first substrate 4 in the laminated glass structure having the intermediate film 10, but the present invention is not limited to this case. For example, the photovoltaic cell 8 may be held at a position spaced apart from both the main surface of the first substrate 4 and the main surface of the second substrate 6 by an intermediate film (filler).

Any of the various embodiments or variants described above can be combined appropriately to achieve the effects of each. In addition, a combination of the embodiments, combinations of examples, or combinations of the embodiments and examples are possible, and combinations of features from different embodiments or examples are also possible.

Although the present disclosure has been fully described in connection with the preferred embodiments with reference to the accompanying drawings, various variations and modifications will be apparent to those skilled in the art, and such variations and modifications are to be understood as being included within the scope of the present disclosure as defined by the appended claims unless they depart therefrom.

### Additional Note

A first aspect of the present disclosure provides a method for manufacturing a power-generation module having a photovoltaic cell and a sealing member arranged between a first substrate and a second substrate, the method comprising: around the photovoltaic cell, applying a material for a first sealing member and applying a material for a second sealing member to the outside of the first sealing member.

A second aspect of the present disclosure provides the method for manufacturing a power-generation module according to the first aspect, wherein when the material for the first sealing member and the material for the second sealing member are applied in a predetermined direction, the application position of the material for the first sealing member is disposed downstream in the predetermined direction relative to the application position of the material for the second sealing member.

A third aspect of the present disclosure provides the method for manufacturing a power-generation module according to the first and second aspects, wherein the material for the first sealing member and the material for the second sealing member are each applied to define a plurality of sides of the power-generation module, the method comprising: further applying the material for the second sealing member to positions where the material for the second sealing member is discontinued in two adjacent sides of the plurality of sides.

A fourth aspect of the present disclosure provides the method for manufacturing a power-generation module according to any one of the first to third aspects, comprising: around the photovoltaic cell, applying the material for the first sealing member, applying the material for the second sealing member to the outside of the first sealing member, and applying a material for a third sealing member to the outside of the second sealing member.

A fifth aspect of the present disclosure provides the method for manufacturing a power-generation module according to any one of the first to fourth aspects, wherein the materials for the first to Nth sealing members (N≥2) are applied around the photovoltaic cell in order from the inside out to form an N-layer sealing structure.

A sixth aspect of the present disclosure provides the method for manufacturing a power-generation module according to any one of the first to fifth aspects, wherein the distance between the first substrate and the second substrate in the thickness direction of the power-generation module is 3 mm or less.

A seventh aspect of the present disclosure provides the method for manufacturing a power-generation module according to any one of the first to sixth aspects, wherein the first sealing member and the second sealing member contain a material having the same function.

An eighth aspect of the present disclosure provides the method for manufacturing a power-generation module according to the seventh aspect, wherein the material having the same function mainly has a function of suppressing the intrusion of water vapor.

A ninth aspect of the present disclosure provides the method for manufacturing a power-generation module according to any one of the first to eighth aspects, wherein the material for the first sealing member and the material for the second sealing member are applied simultaneously.

A tenth aspect of the present disclosure provides an coating device comprising: a first dispensing port for dispensing a material for a first sealing member and a second dispensing port for dispensing a material for a second sealing member, the first and second dispensing ports configured to allow, respectively, application of the material for the first sealing member and application of the material for the second sealing member to the outside of the first sealing member around a photovoltaic cell disposed between a first substrate and a second substrate of a power-generation module.

An eleventh aspect of the present disclosure provides the coating device according to the tenth aspect, further comprising: a first nozzle having the first dispensing port; and a second nozzle having the second dispensing port.

A twelfth aspect of the present disclosure provides the coating device according to the eleventh aspect, wherein the first nozzle and the second nozzle each extend in a first direction, wherein the first dispensing port lies at a position spaced apart from the second dispensing port in the first direction, and wherein when applying the materials for the first sealing member and the second sealing member, the first nozzle and the second nozzle are swept in a second direction intersecting the first direction.

A thirteenth aspect of the present disclosure provides the coating device according to the twelfth aspect, wherein when the first nozzle and the second nozzle are swept in the second direction, the first nozzle is positioned downstream in the second direction relative to the second nozzle.

A fourteenth aspect of the present disclosure provides the coating device according to any one of the eleventh to thirteenth aspects, further comprising: a connection that connects and integrates the first nozzle and the second nozzle.

A fifteenth aspect of the present disclosure provides the coating device according to any one of the tenth to fourteenth aspects, wherein the material for the fsirt sealing member and the material for the second sealing member are supplied to the first dispensing port and the second dispensing port, respectively, from a common supply source.

A sixteenth aspect of the present disclosure provides the coating device according to any one of the tenth to fifteenth aspects, further comprising: a third dispensing port for dispensing a material for a third sealing member, wherein around the photovoltaic cell, the material for the first sealing member is applied, the material for the second sealing member is applied to the outside of the first sealing member, and the material for the third sealing member is applied to the outside of the second sealing member.

A seventeenth aspect of the present disclosure provides the coating device according to any one of the tenth to sixteenth aspects, further comprising: the first dispensing port for dispensing the material for the first sealing member to an Nth dispensing port for dispensing an material for an Nth sealing member (N≥2), wherein the materials for the first to Nth sealing members are applied around the photovoltaic cell in order from the inside out to form an N-layer sealing structure.

An eighteenth aspect of the present disclosure provides an coating device comprising: a first dispensing port for dispensing a material for a first sealing member to an Nth dispensing port for dispensing a material for an Nth sealing member (N≥2), the first to Nth dispensing ports configured so that the materials for the first sealing member to the Nth sealing member (N≥2) are applied in order from the inside out around a photovoltaic cell between a first substrate and a second substrate of a power-generation module.

A nineteenth aspect of the present disclosure provides a power-generation module comprising: a first substrate and a second substrate arranged spaced apart from each other in a thickness direction; a photovoltaic cell disposed between the first substrate and the second substrate; and a sealing member disposed around the photovoltaic cell, wherein the sealing member includes an internal sealing member and an external sealing member disposed outside the internal sealing member, wherein the internal sealing member and the external sealing member are made of different types of materials, and wherein when viewed from the thickness direction, the external sealing member is disposed in a plurality of layers.

The present disclosure is applicable to a power-generation module used in photovoltaic power generation, a method for manufacturing a power-generation module, and an coating device.
2 Power-generation module
4 First substrate
6 Second substrate
8 Photovoltaic cell
10 Intermediate film
12 Internal sealing member

What is claimed is

1. A method for manufacturing a power-generation module having a photovoltaic cell and a sealing member arranged between a first substrate and a second substrate, the method comprising:
around the photovoltaic cell, applying a material for a first sealing member and applying a material for a second sealing member to the outside of the first sealing member.

2. The method for manufacturing a power-generation module according to claim 1, wherein
when the material for the first sealing member and the material for the second sealing member are applied in a predetermined direction, the application position of the material for the first sealing member is disposed downstream in the predetermined direction relative to the application position of the material for the second sealing member.

3. The method for manufacturing a power-generation module according to claim 1, wherein
the material for the first sealing member and the material for the second sealing member are each applied to define a plurality of sides of the power-generation module, the method comprising:
further applying the material for the second sealing member to positions where the material for the second sealing member is discontinued in two adjacent sides of the plurality of sides.

4. The method for manufacturing a power-generation module according to claim 1, comprising:
around the photovoltaic cell, applying the material for the first sealing member, applying the material for the second sealing member to the outside of the first sealing member, and applying a material for a third sealing member to the outside of the second sealing member.

5. The method for manufacturing a power-generation module according to claim 1, wherein
the materials for the first to Nth sealing members (N≥2) are applied around the photovoltaic cell in order from the inside out to form an N-layer sealing structure.

6. The method for manufacturing a power-generation module according to claim 1, wherein
the distance between the first substrate and the second substrate in the thickness direction of the power-generation module is 3 mm or less.

7. The method for manufacturing a power-generation module according to claim 1, wherein
the first sealing member and the second sealing member contain a material having the same function.

8. The method for manufacturing a power-generation module according to claim 7, wherein
the material having the same function mainly has a function of suppressing the intrusion of water vapor.

9. The method for manufacturing a power-generation module according to claim 1, wherein
the material for the first sealing member and the material for the second sealing member are applied simultaneously.

10. An coating device comprising:
a first dispensing port for dispensing a material for a first sealing member and a second dispensing port for dispensing a material for a second sealing member, the first and second dispensing ports configured to allow, respectively, application of the material for the first sealing member and application of the material for the second sealing member to the outside of the first sealing member around a photovoltaic cell disposed between a first substrate and a second substrate of a power-generation module.

11. The coating device according to claim 10, further comprising:
a first nozzle having the first dispensing port; and
a second nozzle having the second dispensing port.

12. The coating device according to claim 11, wherein
the first nozzle and the second nozzle each extend in a first direction, wherein
the first dispensing port lies at a position spaced apart from the second dispensing port in the first direction, and wherein
when applying the materials for the first sealing member and the second sealing member, the first nozzle and the second nozzle are swept in a second direction intersecting the first direction.

13. The coating device according to claim 12, wherein
when the first nozzle and the second nozzle are swept in the second direction, the first nozzle is positioned downstream in the second direction relative to the second nozzle.

14. The coating device according to claim 11, further comprising:
a connection that connects and integrates the first nozzle and the second nozzle.

15. The coating device according to claim 10, wherein
the material for the first sealing member and the material for the second sealing member are supplied to the first dispensing port and the second dispensing port, respectively, from a common supply source.

16. The coating device according to claim 10, further comprising:
a third dispensing port for dispensing a material for the third sealing member wherein
around the photovoltaic cell, the material for the first sealing member is applied, the material for the second sealing member is applied to the outside of the first sealing member, and the material for the third sealing member is applied to the outside of the second sealing member.

17. The coating device according to claim 10, further comprising:
the first dispensing port for dispensing the material for the first sealing member to an Nth dispensing port for dispensing an material for an Nth sealing member (N≥2), wherein
the materials for the first to Nth sealing members are applied around the photovoltaic cell in order from the inside out to form an N-layer sealing structure.
